(19) United States
(12) Patent Application Publication
(10) Pub. No.: US 2025/0309668 A1
(43) Pub. Date: Oct. 2, 2025

(54) Method, Device, Computer Program and Computer-Readable Storage Medium for Reactivating a Capacity of a Battery

(71) Applicant: Bayerische Motoren Werke Aktiengesellschaft, Muenchen (DE)

(72) Inventor: Simon NUERNBERGER, Bad Aibling (DE)

(21) Appl. No.: 18/863,219

(22) PCT Filed: May 2, 2023
(86) PCT No.: PCT/EP2023/061577

§ 371 Date: Nov. 5, 2024

(30) Foreign Application Priority Data
May 25, 2022 (DE) 10 2022 113 186.6

(51) Int. Cl. H02J 7/00; B60L 3/12; B60L 58/12; B60L 58/16; G01R 31/387; G01R 31/392

(52) U.S. Cl. CPC H02J 7/0069; B60L 3/12; B60L 58/12; B60L 58/16; G01R 31/387; G01R 31/392; H02J 7/005; B60L 2240/54

(57) ABSTRACT

In a method for reactivating a capacity of a battery of a motor vehicle, a load on the battery is ascertained. Depending on the ascertained load, a nature of the reactivation of the capacity of the battery is ascertained. Depending on the ascertained nature of the reactivation, at least one discharging operation of the battery is performed with a specified discharging power in order to reactivate the capacity of the battery.

### BACKGROUND AND SUMMARY

The disclosure relates to a method for reactivating a capacity of a battery of a motor vehicle. The disclosure further relates to a device for reactivating a capacity of a battery of a motor vehicle. The disclosure further relates to a computer program for reactivating a capacity of a battery of a motor vehicle. The disclosure further relates to a computer-readable storage medium on which the computer program is stored.

Modern vehicles are often operated purely electrically and for this purpose have a battery, in particular a high-voltage battery. This battery is frequently charged and discharged, and aging effects take place.

An object on which the present disclosure is based is to help ensure the reactivation of a capacity of a battery.

This object is achieved by the features of the present disclosure. Advantageous configurations are indicated in the present disclosure.

The present disclosure relates to a method and a corresponding device for reactivating a capacity of a battery of a motor vehicle.

In the method, a load on the battery is determined. A nature of the reactivation of the capacity of the battery is determined depending on the determined load. Depending on the determined nature of the reactivation, at least one discharging process of the battery is performed with a specified discharge power in order to reactivate the capacity of the battery.

The battery is in particular a high-voltage battery of an electric vehicle or hybrid vehicle, for example a lithium-ion storage battery, in particular with a proportion of silicon on the anode side, such as for example silicon oxide or silicon carbide, for example a proportion between 5%-20%.

In addition to charging, modern wallboxes also permit targeted discharging of a vehicle battery. Targeted discharging can especially be used to help ensure renewed reactivation of a capacity of the battery. The described method performs discharging of this kind such that a capacity of the battery that has been lost for example due to aging effects is at least partly reactivated again.

According to one optional configuration, the load is determined depending on a comparison of data from other vehicles, and/or a deviation of an operating voltage characteristic curve of the battery from an open-circuit voltage characteristic curve of the battery, and/or an aging characteristic value of the battery.

The load on the battery can be determined very accurately especially by a comparison of data from other vehicles, and/or a deviation of an operating voltage characteristic curve of the battery from an open-circuit voltage characteristic curve of the battery, and/or an aging characteristic value of the battery. The aging characteristic value includes for example how old the battery is and/or how many charging cycles have already been carried out.

According to another optional configuration, the nature of the reactivation includes a number of discharging processes and/or a specified depth of discharge of the respective discharging process.

Depending on how heavily the battery was loaded, it may be expedient to perform more intense reactivation. The reactivation can be improved for example with a number of charging processes (the more discharging processes, the better the reactivation) and/or with a depth of discharge (the more intensely the battery is discharged, the better the reactivation).

The number includes for example a single-digit number of repetitions, such as 1, 2, 3 or 4.

The depth of discharge may be indicated for example in stages, such as a first stage in which constant current or constant power is used for discharging, until for example a state of charge (SoC) of the battery between 5% and 10% is reached, wherein the value 0% does not correspond to a completely discharged battery but to a state in which the vehicle stops a driving operation but the battery still has a specified residual capacity. In a second stage, for example constant current or constant power is used for discharging until for example a state of charge of the battery between 0% and 5% is reached or until a specified minimum voltage of the battery representative of a state of charge of 0% is reached. In a third stage, for example discharging using constant current or constant power is followed by discharging using constant voltage (CV) until for example the specified minimum voltage of the battery is reached.

The discharging takes place for example with a discharge power between 0 and 4 kW, in particular between 2 and 3 kW, for example at 3 kW. Very good reactivation is achieved especially with such a low discharge power.

According to another optional configuration, cell symmetrization to compensate for charge differences between individual battery cells of the battery is carried out before the at least one discharging process of the battery.

During cell symmetrization, for example the individual battery cells of the battery are brought to the same voltage value. This can help ensure that the individual battery cells in the discharging process are discharged to the same extent.

According to another optional configuration, the battery is charged to a specified upper charge threshold value with a specified charging power after the at least one discharging process of the battery.

In the case of deep discharge, it is also advantageous to charge more slowly again, in particular in a current-controlled manner, for example with a charging power between 0 and 11 kW, in particular 3 or 11 kW, for example to a state of charge of 10-30%, in particular to 30%. It is subsequently also possible for example to charge as desired to a state of charge of for example 80% also with a charging power of more than 11 kW.

According to another optional configuration, a driver is informed about the determined nature of the reactivation of the capacity of the battery in order to confirm and/or plan the performance of the at least one discharging process.

Since the at least one discharging process and optional charging process requires a certain amount of time and the car is possibly not drivable in this time (for example in the case of discharge below a 0% state of charge), it is advantageous for a driver to be able to plan the reactivation so that it can be carried out for example at night at a wall box and the vehicle is ready for use again the next morning.

According to another optional configuration, a state of charge estimation is recalibrated based on the at least one discharging process.

The very deep discharging and subsequent charging can be used to very accurately determine the residual capacity still held by the battery. It is thus possible to use this to subsequently better estimate the states of charge of the vehicle.

The present disclosure further relates to a computer program for reactivating a capacity of a battery of a motor vehicle, comprising commands which, when the computer program is executed by a computer, cause the computer to execute the method for reactivating a capacity of a battery of a motor vehicle.

The present disclosure further relates to a computer-readable storage medium on which the computer program is stored.

The computer-readable storage medium comprises in particular a medium that can be read by a data processing device and on which the program code is stored.

Exemplary embodiments are explained in more detail below based on the schematic drawings.

### BRIEF DESCRIPTION OF THE DRAWINGS

FIG. 1 shows a flowchart of a program for reactivating a capacity of a battery of a motor vehicle, and

FIG. 2 shows a graph of a residual capacity of a battery over a service life.

### DETAILED DESCRIPTION OF THE DRAWINGS

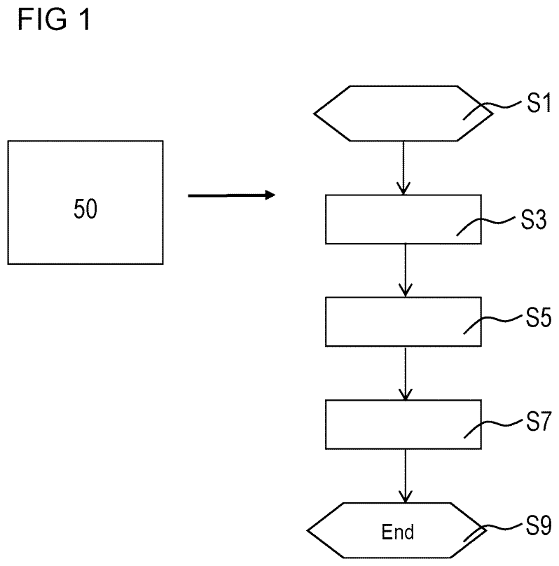

FIG. 1 shows a flow chart of a program for reactivating a capacity of a battery of a motor vehicle.

A device 50 is designed to process the program. The device 50 comprises for this purpose in particular a computation unit, a program and data memory, and for example one or more communication interfaces. The program and data memory and/or the computation unit and/or the communication interfaces may be formed in one modular unit and/or distributed over multiple modular units.

The device 50 can also be referred to as a device for reactivating a capacity of a battery of a motor vehicle.

For this purpose, in particular the program is stored in the program and data memory of the device 50.

The program is started in a step S1, in which variables can be initialized as appropriate.

A load on the battery is determined in a step S3.

The load is determined for example depending on a comparison of data from other vehicles, and/or a deviation of an operating voltage characteristic curve of the battery from an open-circuit voltage characteristic curve of the battery, and/or an aging characteristic value of the battery.

The data from other vehicles include for example data for the residual capacity from comparable other vehicles, that is to say in particular from vehicles with the same battery.

The aging characteristic value includes for example how old the battery is and/or how many charging cycles have already been carried out.

A nature of the reactivation of the capacity of the battery is determined depending on the determined load in a step S5.

The nature of the reactivation includes for example a number of discharging processes and/or a specified depth of discharge of the respective discharging process.

The number includes for example a single-digit number of repetitions, such as 1, 2, 3 or 4.

The depth of discharge may be indicated for example in stages, such as a first stage in which constant current or constant power is used for discharging, until for example a state of charge (SoC) of the battery between 5% and 10% is reached, wherein the value 0% does not correspond to a completely discharged battery but to a state in which the vehicle stops a driving operation but the battery still has a specified residual capacity. In a second stage, for example constant current or constant power is used for discharging until for example a state of charge of the battery between 0% and 5% is reached or until a specified minimum voltage of the battery representative of a state of charge of 0% is reached. In a third stage, for example discharging using constant current or constant power or constant power is followed by discharging using constant voltage (CV) until for example the specified minimum voltage of the battery is reached.

In a step S7, depending on the determined nature of the reactivation, at least one discharging process of the battery is performed with a specified discharge power in order to reactivate the capacity of the battery.

As described above, the discharging takes place differently depending on the stage for example with a discharge power between 0 and 4 kW, in particular between 2 and 3 kW, for example at 3 kW.

If multiple discharging processes are carried out, the battery is recharged to a specified state of charge of for example 10-30% between the discharging processes.

After the last discharging process, the battery can be charged even higher, for example up to an 80% or 100% state of charge.

In the case of deep discharge, it is also advantageous to charge more slowly again, in particular in a current-controlled manner, for example with a charging power between 0 and 11 kW, in particular 3 or 11 kW, for example to a state of charge of 10-30%, in particular to 30%. It is subsequently also possible for example to charge as desired to a state of charge of for example 80% with a charging power of for example more than 11 kW.

Cell symmetrization to compensate for charge differences between individual battery cells of the battery is carried out for example before the discharging process is carried out.

Before the discharging process is carried out, for example a driver is informed about the determined nature of the reactivation of the capacity of the battery in order to confirm and/or plan the performance of the at least one discharging process. In this case, the driver can select for example when the reactivation is carried out and/or how many discharging processes are to take place and/or which stage of the discharging process is carried out and/or to what state of charge the vehicle is to be recharged and/or when the vehicle is to be recharged.

In a step S9, the program is ended and can be restarted anew if required.

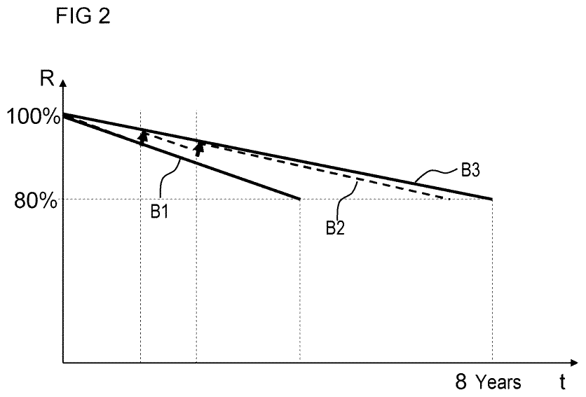

Targeted discharging can especially be used to help ensure renewed reactivation of a capacity of the battery. This is also shown in FIG. 2.

FIG. 2 shows a graph of a residual capacity R of a battery over a service life t in years.

No reactivation has been carried out in the battery B1 and the battery has been operated in a heavily loaded manner, in particular cumulative rapid charging operations have been carried out. The battery has frequently been operated in marginal regions of the state of charge (for example above 80% and below 20%) and/or the battery has been heavily loaded by significant accelerations. As can be seen, such a battery reaches a residual capacity value of 80% relatively quickly, with 100% corresponding to a capacity when new.

The battery B3 has been operated in optimum fashion, that is to say always in an optimum temperature range, at an optimum state of charge, with an optimum driving behavior, parking behavior and charging behavior.

As can be seen, such a battery reaches a residual capacity value of 80% very late, for example after eight years.

Two reactivation processes have been carried out in the battery B2 over the service life (symbolized by arrows); it has otherwise been operated like the battery B1. As can be seen, this battery reaches a residual capacity value of 80% significantly later than the battery B1.

### LIST OF REFERENCE SIGNS

S1-S9 Steps
50 Device
B1, B2, B3 Battery

1-10. (canceled)

11. A method for reactivating a capacity of a battery of a motor vehicle, comprising:
determining a load on the battery;
determining a nature of the reactivation of the capacity of the battery based on the determined load; and
performing at least one discharging process of the battery with a specified discharge power in order to reactivate the capacity of the battery based on the determined nature of the reactivation.

12. The method according to claim 11, comprising:
determining the load on the battery based on:
a comparison of data from other vehicles;
a deviation of an operating voltage characteristic curve of the battery from an open-circuit voltage characteristic curve of the battery; and/or
an aging characteristic value of the battery.

13. The method according to claim 11, wherein the nature of the reactivation includes one or more discharging processes and/or a specified depth of discharge associated with each of the one or more discharging processes.

14. The method according to claim 11, further comprising:
performing cell symmetrization to compensate for charge differences between individual battery cells of the battery prior to the at least one discharging process of the battery.

15. The method according to claim 11, further comprising:
charging the battery to a specified upper charge threshold value with a specified charging power after the at least one discharging process of the battery.

16. The method according to claim 11, further comprising:
informing a driver about the determined nature of the reactivation of the capacity of the battery in order to confirm and/or plan performance of the at least one discharging process.

17. The method according to claim 11, further comprising:
recalibrating a state of charge estimation based on the at least one discharging process.

18. A device for reactivating a capacity of a battery of a motor vehicle, wherein the device is configured to:
determine a load on the battery;
determine a nature of the reactivation of the capacity of the battery based on the determined load; and
perform at least one discharging process of the battery with a specified discharge power in order to reactivate the capacity of the battery based on the determined nature of the reactivation.

19. The device according to claim 18, wherein the device is configured to determine the load on the battery based on:
a comparison of data from other vehicles;
a deviation of an operating voltage characteristic curve of the battery from an open-circuit voltage characteristic curve of the battery; and/or
an aging characteristic value of the battery.

20. The device according to claim 18, wherein the nature of the reactivation includes one or more discharging processes and/or a specified depth of discharge associated with each of the one or more discharging processes.

21. The device according to claim 18, wherein the device is further configured to:
perform cell symmetrization to compensate for charge differences between individual battery cells of the battery prior to the at least one discharging process of the battery.

22. The device according to claim 18, wherein the device is further configured to:
charge the battery to a specified upper charge threshold value with a specified charging power after the at least one discharging process of the battery.

23. The device according to claim 18, wherein the device is further configured to:
inform a driver about the determined nature of the reactivation of the capacity of the battery in order to confirm and/or plan performance of the at least one discharging process.

24. The device according to claim 18, wherein the device is further configured to:
recalibrate a state of charge estimation based on the at least one discharging process

25. A non-transitory computer-readable storage medium having stored thereon a computer program for reactivating a capacity of a battery of a motor vehicle that, when executed by a computer, causes the computer to:
determine a load on the battery;
determine a nature of the reactivation of the capacity of the battery based on the determined load; and
perform at least one discharging process of the battery with a specified discharge power configured to reactivate the capacity of the battery based on the determined nature of the reactivation.

26. The non-transitory computer-readable storage medium of claim 25, wherein the computer program, when executed by the computer, causes the computer to determine the load on the battery based on:
a comparison of data from other vehicles;
a deviation of an operating voltage characteristic curve of the battery from an open-circuit voltage characteristic curve of the battery; and/or
an aging characteristic value of the battery.

27. The non-transitory computer-readable storage medium of claim 25, wherein the nature of the reactivation includes one or more discharging processes and/or a specified depth of discharge associated with each of the one or more discharging processes.

28. The non-transitory computer-readable storage medium of claim 25, wherein the computer program, when executed by the computer, further causes the computer to:
perform cell symmetrization to compensate for charge differences between individual battery cells of the battery prior to the at least one discharging process of the battery.

29. The non-transitory computer-readable storage medium of claim 25, wherein the computer program, when executed by the computer, further causes the computer to:
charge the battery to a specified upper charge threshold value with a specified charging power after the at least one discharging process of the battery.

30. The non-transitory computer-readable storage medium of claim 25, wherein the computer program, when executed by the computer, further causes the computer to:
inform a driver about the determined nature of the reactivation of the capacity of the battery in order to confirm and/or plan performance of the at least one discharging process.
